(19) United States
(12) Patent Application Publication
(10) Pub. No.: US 2011/0259261 A1
(43) Pub. Date: Oct. 27, 2011

(54) REACTION VESSEL FOR GROWING SINGLE CRYSTAL AND METHOD FOR GROWING SINGLE CRYSTAL

(75) Inventors: Makoto IWAI, Kasugai-City (JP); Shuhei Higashihara, Nagoya-City (JP); Yasuo Kitaoka, Suita-City (JP); Yusuke Mori, Suita-City (JP); Takayuki Sato, Kiyosu-Shi (JP); Seiji Nagai, Kiyosu-Shi (JP)

(73) Assignees: NGK Insulators, Ltd., Nagoya-City (JP); Osaka University, Suita-City (JP); Toyoda Gosei Co., Ltd., Kiyosu-Shi (JP)

(21) Appl. No.: 13/177,057

(22) Filed: Jul. 6, 2011

Related U.S. Application Data
(63) Continuation of application No. PCT/JP2009/070271, filed on Nov. 26, 2009.

(30) Foreign Application Priority Data
Jan. 7, 2009 (JP) 2009-001737

(51) Int. Cl. C30B 9/06; C30B 25/00

(52) U.S. Cl. 117/77; 117/88

(57) ABSTRACT

It is provided a method of growing a single crystal by flux process from a melt containing sodium, in that a flux is contained in a reaction vessel made of yttrium-aluminum garnet. Compared with the case that an alumina or yttria vessel is used, it can be successfully obtained a single crystal whose incorporation amounts of oxygen and silicon can be considerably reduced, residual carrier density can be lowered, and electron mobility and specific resistance can be improved.

### TECHNICAL FIELD OF THE INVENTION

The present invention relates to a method of growing a single crystal by means of Na flux process and a reaction vessel used therefor.

### BACKGROUND ARTS

Thin films of gallium nitride crystal has been attracted a substantial attention for a superior blue light emitting diode, and has been practically used for a light emitting diode, and expected for a blue-purple semiconductor laser device for an optical pickup.

Although it has been used crucibles made of p-BN, alumina, tantalum metal, silicon carbide or the like, each of the crucibles exhibits some problems concerning the anti-corrosion property and are susceptible to the dissolving at a small rate (Japanese Patent Publication Nos. 2003-212696A, 2003-286098A, 2005-132663A, 2005-170685A and 2005-263512A).

Particularly when alumina is used, in the grown GaN crystal, aluminum produced by the decomposition of alumina, oxygen and silicon produced by the decomposition of silica component contained in the alumina are incorporated as impurities. Therefore, the applicant disclosed crucibles made of titanium nitride and zirconium nitride as these suitable for Na flux process (Japanese patent publication No. 2006-265069A).

Japanese Patent Publication No. 2005-263535A describes that a crucible of a rare earth oxide, especially yttria, is good.

However, according to “2007 year, Autumn season, the 68'th Conference of the Society of Applied Physics, 4p-2R-6 Presentation documents”, it is difficult to produce such crucible of yttria of a high purity, so that the thus obtained yttria crucible is of a low purity than an alumina crucible. It is described that, although its corrosion resistance is better than that of alumina crucible, the amounts of impurities, especially oxygen amount, contained in the GaN crystal are not improved (refer to page 15).

Further, according to “Atomic energy basic technical data base; data number 110003 (Development of anti-corrosion ceramics)” in the field of atomic energy, it is described general anti-corrosion property data against Na metal. It is further described that alumina, yttria and YAG are superior in the anti-corrosion property.

### DISCLOSURE OF THE INVENTION

On the viewpoint of simply anti-corrosion property against Na metal, it is not found a reduction of weight in any of alumina and yttria crucibles, and so that it should have been used for crystal growth from Na flux without problems. Actually, however, impurities such as oxygen and silicon are incorporated into the thus obtained nitride single crystal, for example gallium nitride single crystal. The oxygen and silicon impurities functions as n-type carrier to reduce the insulating property. Therefore, for stably producing electronic devices by preventing the conductivity of gallium nitride single crystal, it is necessary to prevent the incorporation of trace amounts of oxygen and silicon from the crucible material.

An object of the invention is, in growing a single crystal from a melt containing sodium by means of flux process, to prevent the incorporation of dopants such as oxygen, silicon or the like from the material of a reaction vessel so that a single crystal of high insulating property can be obtained.

The present invention provides a reaction vessel used for growing a single crystal from a melt containing sodium by means of flux process, the vessel comprising yttrium-aluminum garnet.

The present invention further provides a method of containing a melt containing sodium in a reaction vessel comprising yttrium-aluminum garnet and growing a single crystal by means of flux process from the melt.

The present inventors have tried to grow a single crystal using a reaction vessel made of yttrium-aluminum garnet by means of flux process. As a result, compared with the case that an alumina or yttria vessel is used, it is proved that it is possible to considerably reduce an amount of incorporation of impurities such as oxygen, silicon or the like. It is thereby possible to successfully obtain a single crystal having a low residual carrier concentration, a high electron mobility and a high relative resistance.

Besides, it is not observed a reduction of weight after the reaction in the case of using the alumina or yttria vessel. The effects of the present invention is thus, different from conventional anti-corrosion property, related to the incorporation of trace amounts of dopants such as oxygen, silicon or the like from the reaction vessel with good anti-corrosion property into the single crystal. The present invention cannot thus be predicted from prior arts.

### EMBODIMENTS FOR CARRYING OUT THE INVENTION

The reaction vessel referred to as in the present invention generally means a vessel contacting liquid or vapor of a flux, and a concept including, for example, a crucible, a pressure vessel and an outer reaction container containing the crucible. The present invention is particularly advantageous in the case that it is applied to a crucible for directly containing and melting a flux.

Yttrium-aluminum garnet forming the reaction vessel may be a single crystal or poly crystal (ceramics).

The average grain size of the yttrium-aluminum garnet poly crystal may preferably be 1 to 100 μm on the viewpoint of anti-corrosion property against a flux. On the viewpoint, the grain size of the powdery raw material may preferably be 0.1 μm or more and 10 μm or less.

Further, the Young's modulus of yttrium-aluminum garnet forming the reaction vessel may preferably be 100 GPa or higher and more preferably be 200 GPa or higher. It is thereby possible to further improve the corrosion resistance of the reaction vessel.

Further, the relative density of yttrium-aluminum garnet may preferably be 98 percent or more on the viewpoint of corrosion resistance against the flux.

The method of producing yttrium-aluminum garnet is not limited. In the case of yttrium aluminum garnet ceramics, for example, powdery raw materials are mixed and molded. The method of molding includes uniaxial press, cold isostatic press and casting. Further, it may be used a binder such as PVA (polyvinyl alcohol) and PVB (polyvinyl butyral) for the molding.

Dewaxing can be carried out after the molding. The temperature of the dewaxing is not particularly limited and may be 300° C. or higher and further 400° C. or higher, for example. Further, the upper limit of the temperature of the dewaxing is not particularly limited, and may be 600° C. or lower and further 500° C. or lower.

The method of sintering is not particularly limited, and includes ambient pressure sintering under reducing atmosphere, hot press, hot isostatic press and discharge plasma sintering. The sintering temperature is not limited and may be 1700 to 2000° C., for example.

In the case that yttrium-aluminum garnet is a single crystal, it may preferably be produced by Czochralski or Kyropoulos method.

A part of the yttrium site of yttrium-aluminum garnet forming the reaction vessel may be substituted by a rare earth element other than yttrium. Such rare earth element includes gadolinium, cerium, ytterbium, neodymium, lanthanum, erbium and scandium. Further, the ratio of substitution of yttrium may preferably be 50 mol percent or lower and more preferably be 10 mol percent or lower.

A part of the aluminum site of yttrium-aluminum garnet forming the reaction vessel may be substituted by a transition metal other than aluminum. Such transition metal includes iron, gallium and chromium. Further, the ratio of substitution of aluminum may preferably be 50 mol percent or lower and more preferably be 10 mol percent or lower.

According to a preferred embodiment, the crucible containing the flux is contained in a pressure vessel and then heated at a high pressure in a system for hot isostatic press. The crucible may be made of the ceramic material of the present invention. In this case, atmospheric pressure gas containing nitrogen gas may be compressed at a predetermined pressure and supplied into the pressure vessel so as to control the total pressure and nitrogen pressure in the pressure vessel.

Gallium, aluminum, indium, boron, zinc, silicon, tin, antimony or bismuth may be added to the sodium flux, for example.

The following single crystals can be appropriately produced, for example, according to the growing method of the present invention.

GaN, AlN, InN, the mixed crystal (AlGaInN), and BN. The heating temperature and pressure in the step of growing a single crystal is selected depending on the kind of the single crystal and not particularly limited. For example, the heating temperature may be made 800 to 1500° C., and preferably be 800 to 1200° C. and more preferably be 800 to 1100° C., The pressure is not particularly limited, and preferably be 1 MPa or higher, more preferably be 2 MPa or higher. Although the upper limit of the pressure is not particularly limited, it may be 200 MPa or lower and preferably be 100 MPa or lower.

Further, specific single crystals and the growing procedures will be described below.

### Embodiment of Growing Gallium Nitride Single Crystal

According to the present invention, the flux containing at least sodium may be used to grow gallium nitride single crystal. A gallium raw material is dissolved into the flux. As the gallium raw material, a simple substance metal of gallium, a gallium alloy and a gallium compound may be utilized, and the simple substance metal of gallium is preferable in terms of handling.

The flux may contain a metal other than sodium such as lithium for example. Mole fractions of the gallium raw material and a flux raw material of sodium may be appropriately decided, and generally an excessive amount of sodium may be preferably used, although such is not restrictive.

According to this embodiment, gallium nitride single crystal is grown under atmosphere of mixed gases containing nitrogen gas at a total pressure of 1 MPa or higher and 200 MPa or lower. By making the total pressure at 1 MPa or higher, it is possible to grow gallium nitride single crystal of good quality at a high temperature range of 800° C. or higher and more preferably 850° C. or higher.

According to a preferred embodiment, the nitrogen partial pressure of atmosphere during the growth is made 1 MPa or higher and 200 MPa or lower. By making the nitrogen partial pressure to 1 MPa or higher, it is possible to assist the dissolution of nitrogen into the flux and to grow gallium nitride single crystal of good quality, for example at a high temperature range of 800° C. or higher. On the viewpoint, the nitrogen partial pressure may preferably be 2 MPa or higher. Further, on the practical point of view, the nitrogen partial pressure may preferably be 100 MPa or lower.

Gases other than nitrogen in the atmosphere is not limited, and may preferably be an inert gas, and argon, helium and neon are particularly preferable. The partial pressure of the gas other than nitrogen is a value obtained by subtracting the nitrogen partial pressure from a total pressure.

According to a preferred embodiment, gallium nitride single crystal may preferably be grown at a temperature of 800° C. of higher and more preferably of 850° C. or higher. Gallium nitride single crystal of good quality can be grown in such high temperature range. Further, the productivity may be improved by the growth at such high temperature and high pressure range.

Although the upper limit of growth temperature of gallium nitride single crystal is not particularly limited, it may be 1500° C. or lower because too high temperature may reduce the growth of the crystal. On the viewpoint, the growth temperature may preferably 1200° C. or lower.

The material of a growth substrate for epitaxially growing a gallium nitride crystal may include, but not limited to, sapphire; an AlN template; a GaN template; a GaN self-standing substrate; a silicon single crystal; a SiC single crystal; an MgO single crystal; a spinelle (MgAl₂O₄); LiAlO₂; LiGaO₂; and a perovskite-type composite oxide such as LaAlO₃, LaGaO₃, NdGaO₃, or the like. Further, it is also possible to use a composite oxide having a cubic-system perovskite structure whose composition formula is [A_{1-y}(Sr₁₋ₓBaₓ)_{y}][Al_{1-z}Ga_{z}]₁₋ᵤ·Dᵤ]O₃ (where A is a rare earth element, D is at least one element selected from a group of niobium and tantalum, y=0.3 to 0.98, x=0 to 1, z=0 to 1, u=0.15 to 0.49, and x+z=0.1 to 2). Still further, SCAM (ScAlMgO₄) may be used.

### Embodiment of Growth of AlN Single Crystal

The present invention is proved to be effective in the case that melt containing flux containing at least aluminum and an alkaline earth metal under nitrogen containing atmosphere under specific conditions to grow AlN single crystal.

### EXAMPLES

### Example 1

It was used a cylindrical crucible with a flat bottom and having an inner diameter of 70 mm and a height of 50 mm. Raw materials for growth (Ga metal 60 g; Na metal 60 g; carbon 0.1 g) were melted respectively in a glove box and then supplied into the crucible made of YAG (yttrium-aluminum garnet; Y₃Al₅O₁₂). The yttrium-aluminum garnet used in the present example has the following characteristics.

Purity: 99.99%

Amount of Si impurity<10 ppm

First, Na was filled and Ga was then filled into the crucible so as to shield Na from the atmosphere and thereby to prevent the oxidation of Na. The height of melt within the crucible was about 20 mm. Then, on a table for supporting a seed crystal set in the crucible, one GaN template (A sapphire substrate with a GaN single crystal thin film formed on the surface in a thickness of 8 micron) having a diameter of 2 inches was positioned in an inclined manner. After the crucible was installed in a container of stainless steel and sealed, the container was mounted on a table, which can be rotated and shaken, in a crystal growth furnace. After the temperature and pressure of the furnace were elevated to 870° C. and 4.5 MPa, they were maintained for 100 hours while the container was shaken and rotated for the agitation to grow the crystal. Thereafter, the furnace was cooled over 10 hours to room temperature, and the crystal was collected.

The thus grown crystal was GaN crystal having a thickness of about 1.5 mm over the whole surface of the 2-inch seed substrate. The deviation of the thickness of the crystal in the crystal plane was as small as lower than 10%. The crystal was subjected to analysis of impurities by means of SIMS to prove that the oxygen concentration was 5×10¹⁶ atoms/cm³ and the silicon concentration was 1×10¹⁶ atoms/cm³, respectively. The residual carrier concentration, electron mobility and specific resistance were measured to prove to be 1×10¹⁶ atoms/cm³, 800 cm²/V·sec and 0.5 Ω·cm, respectively

### Comparative Example 1

The crystal growth was performed according to the procedures as the Example 1, except that an alumina crucible was used. The thus obtained crystal was subjected to impurity analysis by means of SIMS to prove that the oxygen concentration was 1×10¹⁷ atoms/cm³ and the silicon concentration was 5×10¹⁶ atoms/cm³, respectively. Alumina was further incorporated in a concentration of 1×10¹⁷ atoms/cm³. It is considered that alumina and silica were dissolved from the alumina crucible.

By means of measurement of holes, the residual carrier concentration, electron mobility and specific resistance were measured to prove to be 8×10¹⁶ atoms/cm³, 560 cm²/V·sec and 0.1 Ω·cm, respectively

### Comparative Example 2

The crystal was grown according to the same procedure as the Example 1 except that a tungsten crucible was used. The thus obtained crystal was colored to green. The impurities in the sample were analyzed by means of SIMS to prove that Fe, Mo, Si etc. were detected.

### Comparative Example 3

The crystal was grown according to the same procedure as the Example 1 except that a tantalum crucible was used. The thus obtained crystal was slightly colored to brown. The impurities in the sample was analysed by means of SIMS to prove that Fe and Nb were detected.

As described above, when a nitride single crystal was grown by flux process using a crucible of yttrium-aluminum garnet, the oxygen and silicon concentrations were reduced, the residual carrier density was decreased and the electron mobility was improved in the grown crystal.

Although the specific embodiments of the present invention have been described, the present invention is not limited thereto, and various changes or modifications may be made in the invention without departing from the scope of the invention.

1-2. (canceled)

3. A method of growing a nitride single crystal by flux process, the method comprising the steps of:
containing a melt comprising sodium and a raw material for said nitride single crystal, excluding barium, in a crucible comprising yttrium-aluminum garnet, and
heating and pressurizing said melt under atmosphere comprising nitrogen to grow said nitride single crystal.

4. The method of claim 3, wherein said melt comprises sodium and a substance selected from the group consisting of gallium, aluminum, indium, boron, zinc, silicon, tin, antimony and bismuth.

5. The method of claim 3, wherein said nitride single crystal comprises GaN, AlN, InN, AlGaInN or BN.

6. The method of claim 5, wherein said nitride single crystal comprises GaN.

7. The method of claim 3, wherein said nitride single crystal comprises GaN and wherein said melt comprises sodium and a raw material of gallium.

8. The method of claim 3, wherein said nitride single crystal comprises GaN and wherein said melt comprises sodium, a raw material of gallium and lithium.

9. The method of claim 3, wherein said pressurizing is performed at a pressure of 1 MPa or higher and 200 MPa or lower and wherein the heating is performed at a temperature of 800° C. or higher and 1500° C. or lower.

10. The method of claim 3, wherein said yttrium-aluminum garnet comprises a polycrystal having an average grain size of 1 μm or larger and 100 μm or smaller.

11. The method of claim 3, wherein said yttrium-aluminum garnet has a Young's modulus of 100 GPa or higher.

12. The method of claim 3, wherein said yttrium-aluminum garnet has a relative density of 98% or higher.
